(19) United States
(12) Patent Application Publication
(10) Pub. No.: US 2017/0179382 A1
(43) Pub. Date: Jun. 22, 2017

(54) LOW LEAKAGE RESISTIVE RANDOM ACCESS MEMORY CELLS AND PROCESSES FOR FABRICATING SAME

(71) Applicant: Microsemi SoC Corporation, San Jose, CA (US)

(72) Inventors: John L. McCollum, Orem, UT (US); Fethi Dhaoui, Mountain House, CA (US); Frank W. Hawley, Campbell, CA (US)

(73) Assignee: Microsemi SoC Corporation, San Jose, CA (US)

(21) Appl. No.: 15/374,957

(22) Filed: Dec. 9, 2016

Related U.S. Application Data
(60) Provisional application No. 62/268,699, filed on Dec. 17, 2015.

(51) Int. Cl. H01L 45/00; H01L 27/24; G11C 13/00

(52) U.S. Cl. CPC H01L 45/085; H01L 45/1233; H01L 45/1246; H01L 45/1608; H01L 45/1253; G11C 13/0011; G11C 13/0069; G11C 13/0097; H01L 27/2463; G11C 2213/11; G11C 2213/51; G11C 2213/52; G11C 2213/54; G11C 2213/56

(57) ABSTRACT

A resistive random access memory device is formed in an integrated circuit between a first metal layer and a second metal layer and includes a first barrier layer disposed over the first metal layer, a tunneling dielectric layer disposed over the first barrier layer, a solid electrolyte layer disposed over the tunneling dielectric layer, an ion source layer disposed over the solid electrolyte layer, and a second barrier layer disposed over the ion source layer.

### CROSS REFERENCE TO RELATED APPLICATIONS

This application claims the benefit of U.S. Provisional Patent Application No. 62/268,699 filed Dec. 17, 2015, the contents of which are incorporated in this disclosure by reference in its entirety.

### BACKGROUND

1. Field of the Invention

The present invention relates to semiconductor technology. More particularly, the present invention relates to memory cell technology and to resistive random access memory cell technology. The present invention relates to low leakage resistive random access memory (ReRAM) cells.

The contents of co-pending applications attorney docket no. 7618-52198-1 entitled LOW LEAKAGE ReRAM FPGA CONFIGURATION CELL; attorney docket no. 7618-52597-1 entitled THREE-TRANSISTOR RESISTIVE RANDOM ACCESS MEMORY CELLS; and attorney docket no. 7618-52666-1 entitled THREE-TRANSISTOR RESISTIVE RANDOM ACCESS MEMORY CELLS filed on the same date of this application are expressly incorporated herein by reference in their entirety.

2. The Prior Art

ReRAM push-pull memory cells make an attractive configuration memory for advanced field-programmable gate array (FPGA) integrated circuits due to their small size and scalability. Examples of ReRAM memory devices and memory cells configured from those devices are disclosed in U.S. Pat. No. 8,415,650.

A ReRAM device is basically two metal plates, one of which serves as a metal ion source, separated by a solid electrolyte. The solid electrolyte has two states. In a first state (an “on” state), ions from the metal ion source have been forced into the electrolyte by placing a DC voltage having a first polarity across the ReRAM device and having a sufficient potential to drive metal ions from the ion-source plate into the electrolyte. In the first state, the ions form a conductive bridge through the solid electrolyte across which electrons can pass fairly easily. As the electrolyte becomes increasingly populated with metal ions, its resistivity, and hence the resistivity of the entire ReRAM device, decreases. In a second state (an “off” state), the electrolyte has been virtually depleted of ions by placing a DC voltage having a polarity opposite to that of the first potential and a potential sufficient to drive the metal ions from the electrolyte back into the ion-source plate across the ReRAM device. In the second state, absence of the ions makes it difficult for electrons to pass through the solid electrolyte. As the population of metal ions in the electrolyte decreases, its resistivity, and hence the resistivity of the entire ReRAM device increases. Amorphous silicon is a solid electrolyte and it is a leading candidate today for use in ReRAM devices.

ReRAM devices are often employed in a push-pull configuration to form a ReRAM memory cell as shown in FIG. 1. ReRAM memory cell 10 includes a first ReRAM device 12 in series with a second ReRAM device 14. In the ReRAM device symbols shown in FIG. 1, the wider (bottom) end of the ReRAM device is the end nearest its ion source. A voltage applied across the ReRAM device with its positive potential at the narrower (top) end of the ReRAM device will erase the device, i.e., set it to its “off” state, and a voltage applied across the ReRAM device with its positive potential at the wider (bottom) end of the ReRAM device will program the device i.e., set it to its “on” state.

The ReRAM devices 12 and 14 are connected in series between a pair of complementary bitlines (BL) 16 (BL!) 18. Persons of ordinary skill in the art will appreciate that the value of the potentials applied to (BL) 16 and (BL!) 18 will be selected as a function of the particular feature size and other aspects of the technology employed. Typical voltages that are applied to (BL) 16 and (BL!) 18 during its operating mode are 1.5V and 0V, respectively.

In operation, one of ReRAM devices 12 and 14 will be set to its “on” state and the other will be set to its “off” state. Depending on which one of the ReRAM devices 12 and 14 is “on” and which one is “off” switch node 20 will either be pulled up to the voltage on BL 16 or pulled down to the voltage on BL! 18.

The gate of a switch transistor 22 is coupled to switch node 20. The drain of the switch transistor is connected to a first programmable node 24 and the source of the switch transistor is connected to a second programmable node 26. The first programmable node 24 can be connected to the second programmable node 26 by turning on the switch transistor 22.

If ReRAM device 12 is in its “on” state and ReRAM device 14 is in its “off” state, switch node 20 is pulled up to the voltage on BL 16, and switch transistor 22 will be turned on. If ReRAM device 12 is in its “off” state and ReRAM device 14 is in its “on” state, switch node 20 is pulled down to the voltage on BL! 18, and switch transistor 22 will be turned off. Persons of ordinary skill in the art will note that the entire potential between (BL) 16 and (BL!) 18 will exist across the one of ReRAM devices 12 and 14 that is in the “off” state.

A programming transistor 28 has a gate coupled to a word line (WL) 30. The drain of programming transistor 28 is connected to switch node 20 and its source is connected to word line source (WLS) 32. In a typical application, ReRAM devices 12 and 14 are first erased (set to their “off” state) and then one of them is programmed (set to its “on” state) as described herein with reference to FIG. 8 and FIG. 9. During the operating mode of the ReRAM cell 10, WL is set to 0V and programming transistor 28 is turned off.

Referring now to FIG. 2, a cross sectional view of an illustrative semiconductor layout for a ReRAM cell 10 like that of FIG.1 is shown. The ReRAM cell 10 is shown formed in a p-type semiconductor substrate 34, which may be a p-well structure as is known in the art. Shallow trench isolation (STI) regions 36 separate active regions for the switch transistor 22, the programming transistor 28 and other adjacent structures. N-type doped region 38 forms the drain of the programming transistor 28 and n-type region 40 forms its source. A contact 42 connects source 40 of the programming transistor 28 to a first segment 44 of a first layer (M1) of metal interconnect. Polysilicon line 46 forms the gate of the programming transistor 28 and also acts as word line WL 30. Persons of ordinary skill in the art will appreciate that n-type region 40 can also serve as the source of a programming transistor 28 for an adjacent ReRAM cell configured in a mirror cell arrangement with ReRAM memory cell 10 as is known in the art.

The switch transistor 22 is oriented orthogonally to the programming transistor 28 and polysilicon line 48 forms its gate. The source 26 and drain 24 regions of the switch transistor 22 are located in planes behind and in front of the plane of FIG. 2. Region 50 under the polysilicon line 48 is the channel of the switch transistor 22.

ReRAM device 12 is formed between a second segment 52 of the first layer (M1) of metal interconnect and a first segment 54 of a second layer (M2) of metal interconnect. An inter-metal contact 56 is shown connecting ReRAM device 12 to the first segment 54 of the second layer (M2) of metal interconnect. A second segment 58 of the second layer (M2) of metal interconnect serves as the bitline BL 16 and is connected to the second segment 52 of the first layer (M1) of metal interconnect by an inter-metal contact 60.

ReRAM device 14 is formed between a third segment 62 of the first layer (M1) of metal interconnect and a third segment 64 of the second layer (M2) of metal interconnect. The third segment 64 of the second layer (M2) of metal interconnect serves as the bitline BL!. An inter-metal contact 66 is shown connecting ReRAM device 14 to the third segment 64 of the second layer (M2) of metal interconnect.

An inter-metal contact 68 between the first segment 54 of the second layer (M2) of metal interconnect and the third segment 62 of the first layer (M1) of metal interconnect is used to make the connection between ReRAM device 12 and ReRAM device 14. Another pair of inter-metal contacts 70 and 72 and the third segment 62 of the first layer (M1) of metal interconnect are used to make the connection between the gate 48 of the switch transistor, the drain 38 of the programming transistor, and the common connection of the ReRAM devices 12 and 14.

Referring now to FIG. 3, a cross-sectional view shows an illustrative prior-art ReRAM device 80. ReRAM device 80 is formed over a metal interconnect layer which, in the illustrative example shown in FIG. 3 is formed as a damascene copper interconnect layer or deposited tungsten via 84 in an interlayer dielectric layer 82. The damascene copper interconnect layer or deposited tungsten via 84 formed in the interlayer dielectric layer 82 surrounded by a Cu or W barrier layer 86 as is known in the art.

The ReRAM structure depicted in FIG. 3 is similar to those depicted in FIGS. 6-12 of prior U.S. Pat. No. 8,415,650 the entire contents of which is incorporated herein by reference. The teachings of U.S. Pat. No. 8,415,650 are directed to avoiding problems due to seams in metal layers as discussed therein. Metal layer seams presented issues in ReRAM devices that used the programming mechanisms disclosed therein. Although it is believed that the metal seams may be an artifact in the ReRAMs according to the present invention, they do not affect the performance of the devices. The programming mechanisms employed for the ReRAM devices of the present invention are different from those employed in the ReRAM devices disclosed in U.S. Pat. No. 8,415,650. The seams and the artifacts they create in the overlying layers are not shown in the drawing figures depicting various embodiments of the invention.

The tungsten via or damascene copper metal line 84 is surrounded by a barrier layer 86. A Chemical Mechanical Polishing (CMP) stop layer may be formed over the top of the inter-metal dielectric layer for use in the process employed to planarize the top of the tungsten via or damascene copper metal line 84 as is known in the art. SiN or SiC are commonly employed as CMP stop layers.

Persons of ordinary skill in the art will appreciate that the CMP stop layers may not be required and are optional. Their use or non-use will depend on the CMP technology used by the manufacturer. Some CMP processes may be able to have a timed polish step and do not need the CMP stop layer. This is preferred because it makes the process of depositing the dielectric layers simpler. In addition, the removal of SiN which has a dielectric constant of 7 and its replacement with silicon oxide which has a dielectric constant of 4 is preferred and will reduce the coupling capacitance of the metal layers, thus improving the speed performance of the device.

In the ReRAM device depicted in FIG. 3, a layer 88 of a barrier metal is formed above the tungsten via or damascene copper metal line 82. The barrier metal layer 88 may be formed from a material such as Ta, TaN, Ti or TiN, W or other suitable material.

A solid electrolyte layer 90 is formed above barrier metal layer 88. The solid electrolyte layer may be formed from a deposited layer of amorphous silicon. An ion source layer 92 is formed over the solid electrolyte layer 90 and is formed from a material such as Ag, since Cu may be difficult to plasma etch.

The stack of layers 88, 90, and 92 is etched to form an aligned stack. A dielectric barrier layer 94 formed from a material such as SiN or SiC is formed over the defined stack. A via is formed in the dielectric barrier layer 94 to expose the upper surface of ion source layer 92. A barrier metal layer 100 is then formed over the dielectric barrier layer and makes contact with ion source layer 92. A top metal may be in the form of a damascene copper metal line, a plug formed from tungsten or another metal used for interconnect layers in integrated circuits. The particular embodiment shown in FIG. 3 employs another inter-layer dielectric 96 in which a tungsten via or damascene copper metal line 98 is formed, shown including a Cu or W barrier layer 100 as appropriate and as known in the art.

ReRAM devices in the “off” state do not exhibit infinite resistance. ReRAM devices will therefore pass a leakage current in the “off” state if a voltage is impressed across them. For most normal memory applications, bits are only read when they are addressed. A transistor may be used to block any leakage current during times when the bit is not being read, and thus the leakage is not overly problematic.

However, when using a ReRAM cell as a configuration memory for an FPGA, the cell statically drives the gate of a switch transistor to place the switch transistor in either its “on” or “off” state. In this application, the ReRAM cell is essentially always being read. Thus, the leakage current is always present across the ReRAM device that is in the “off” state, if a voltage is impressed thereacross, and is problematic.

Current investigations of the use of ReRAM memory cells as configuration memory in FPGA integrated circuits are academic in nature and ignore the cell leakage issue which presents a practical problem inhibiting the commercial application of this technology.

### BRIEF DESCRIPTION

According to one aspect of the present invention, a ReRAM device is formed in an integrated circuit between a first metal layer and a second metal layer and includes a first barrier layer disposed over the first metal layer, a tunneling dielectric layer disposed over the first barrier layer, a solid electrolyte layer disposed over the tunneling dielectric layer, an ion source layer disposed over the solid electrolyte layer, and a second barrier layer disposed over the ion source layer.

According to another aspect of the present invention, a ReRAM device is formed in an integrated circuit between a first metal layer and a second metal layer and includes a first barrier layer disposed over the first metal layer, a solid electrolyte layer disposed over the first barrier layer, a dielectric layer disposed over the solid electrolyte layer, an ion source layer disposed over the dielectric layer, and a second barrier layer disposed over the ion source layer and beneath the second metal layer.

According to another aspect of the present invention, a ReRAM device is formed in an integrated circuit between a first metal layer and a second metal layer and includes a first barrier layer disposed over the first metal layer, a tunneling dielectric layer disposed over the first barrier layer, a solid electrolyte layer disposed over the tunneling dielectric layer, a dielectric layer disposed over the solid electrolyte layer, an ion source layer disposed over the dielectric layer, and a second barrier layer disposed over the ion source layer and beneath the second metal layer.

According to other aspects of the invention, the first and second metal layers can include any combination of a conventional deposited metal layer, a plug or via, such as a tungsten plug, a damascene copper metal line, etc. The barrier layer may be formed from materials that are known to serve as barrier layers for metals that are employed as the first and second metal layers. The solid electrolyte may be formed from amorphous silicon and the ion source may be formed from a material such as silver.

### BRIEF DESCRIPTION OF THE DRAWING FIGURES

FIG. 1 is a schematic diagram of an illustrative push-pull ReRAM cell of the prior art to show the environment in which the present invention will typically function.

FIG. 2 is a cross sectional view of an illustrative semiconductor layout for a ReRAM cell of the prior art like that shown in FIG.1.

FIG. 3 is a cross-sectional view of an illustrative prior-art ReRAM device.

FIG. 4 is a cross-sectional view of an illustrative ReRAM device in accordance with a first aspect of the present invention.

FIG. 5 is a cross-sectional view of an illustrative ReRAM device in accordance with another aspect of the present invention.

FIG. 6 is a cross-sectional view of an illustrative ReRAM device in accordance with yet another aspect of the present invention.

FIGS. 7A through 7G are cross-sectional views of an illustrative ReRAM device showing the structure resulting after various steps in the semiconductor fabrication process have been performed.

FIG. 8 is a schematic diagram depicting four illustrative ReRAM cells in an array to show a method for programming and erasing the ReRAM cells.

FIG. 9 is a table showing voltages to be applied to the ReRAM memory array of FIG. 8 to erase and program the cells.

### DETAILED DESCRIPTION

Persons of ordinary skill in the art will realize that the following description of the present invention is illustrative only and not in any way limiting. Other embodiments of the invention will readily suggest themselves to such skilled persons.

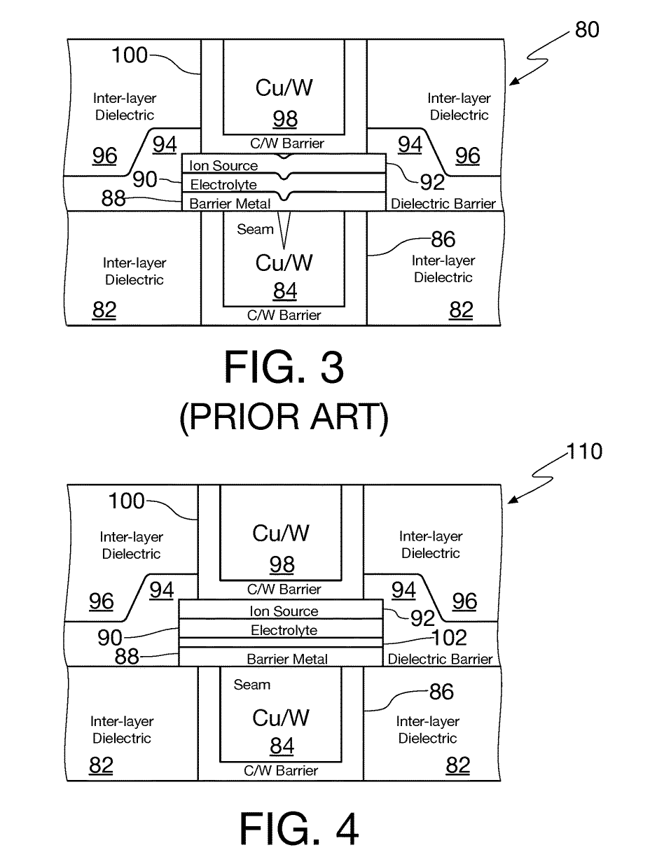

Referring now to FIG. 4, a diagram shows a cross-sectional view of an illustrative ReRAM device 110 in accordance with a first aspect of the present invention. For convenience, structures in the embodiment of FIG. 4 that are similar to structures shown in FIG. 3 will be designated using the same reference numerals used in FIG. 3.

ReRAM device 110 is formed over a metal interconnect layer which, in the illustrative embodiment shown in FIG. 4 is formed as a damascene copper interconnect layer or a deposited tungsten via 84 in an interlayer dielectric layer 82. The damascene copper interconnect layer or deposited tungsten via 84 formed in the interlayer dielectric layer 82 is surrounded by a Cu or W barrier layer 86 as is known in the art. Persons of ordinary skill in the art will appreciate that the metal interconnect layer could also be a conventional deposited metal interconnect layer.

The tungsten via or damascene copper metal line 84 is shown surrounded by a barrier layer 86. A CMP stop layer may be formed over the top of the inter-metal dielectric layer 82 and is used in the process employed to planarize the top of damascene copper interconnect layer or tungsten via 84 as is known in the art. SiN or SiC are commonly employed as CMP stop layers.

Persons of ordinary skill in the art will appreciate that the CMP stop layers may not be required and are optional. Their use or non-use will depend on the CMP technology used by the manufacturer. Some CMP processes may be able to have a timed polish step and do not need the CMP stop layer. This is preferred because it makes the process of depositing the dielectric layers simpler. In addition, the removal of SiN which has a dielectric constant of 7 and its replacement with silicon oxide which has a dielectric constant of 4 is preferred and will reduce the coupling capacitance of the metal layers, thus improving the speed performance of the device.

In the ReRAM device depicted in FIG. 4, a layer 88 of a barrier metal is formed above the tungsten via or damascene copper metal line 84 (or other metal interconnect line). The barrier metal layer 88 may be formed from a material such as Ta, TaN, Ti or TiN, W or other suitable material.

It is known that electrons can be made to tunnel across an ultra-thin dielectric layer, i.e., one that is less than 35 Å. According to one aspect of the present invention, an tunneling dielectric layer 102 formed from a material such as SiN, is deposited over the barrier metal layer 88, as an ultra-thin layer. This tunneling dielectric layer will reduce leakage in the “off” state. During the “on” state it will limit current flow through the ReRAM, although current sufficient to bias the switch node to the proper voltage will still flow.

A solid electrolyte layer 90 is formed above tunneling dielectric layer 102. The solid electrolyte layer 90 may be formed from a deposited layer of amorphous silicon. Other materials, such as chalcogenides (e.g., Ge₂Sb₂Te₅ or AgInSbTe), NiO or TiO2, Ge or GeSe, TaOx may also be used. The thickness of the solid electrolyte layer 90 may range from about 50 Å to about 500 Å, a typical thicknesses being from about 200 Å to about 300 Å.

An ion source layer 92 is formed over the solid electrolyte layer 90 and is formed from a material such as Ag. Other materials, such as copper, and TiO₂ may be used. The thickness of the ion source layer 92 may range from about 100 Å to about 2,000 Å, typical thicknesses being from about 300 Å to about 500 Å.

The stack of layers 88, 102, 90, and 92 is etched to form an aligned stack using conventional stack etching techniques. A dielectric barrier layer 94 formed from a material such as deposited SiN or SiC is formed over the defined stack. A via is formed in the dielectric barrier layer 94 to expose the upper surface of ion source layer 92. A barrier metal layer 100 is then formed over the dielectric barrier layer and makes contact with ion source layer 92. A top metal may be formed as a damascene copper or tungsten plug 98 or from Al or another metal used for interconnect layers in integrated circuits. The embodiment shown in FIG. 4 employs another inter-layer dielectric 96 in which the tungsten via or damascene copper metal line 98 is formed.

During the “on” state, the electrolyte is well populated with ions and has a relatively low resistance, allowing electrons to flow through it. Because electrons will tunnel through the tunneling dielectric layer 102, the tunneling dielectric layer 102 will act as a resistance. It is expected that, for a 1V cell, about 1 μA will pass through the dielectric tunneling layer 102.

During the “off” state, the electrolyte layer 90 is not well populated with ions and has a relatively high resistance, so there will be few electrons flowing through it. Under these conditions, the tunneling dielectric layer 102 will then act as a very high resistance, thus reducing the “off” state leakage. It is important to note that the current through the tunneling dielectric 102 is a function of the number of electrons present at the potential barrier and the e-field across the barrier. The tunneling dielectric layer 102 presents a high resistance during the “off” state because the lower population of electrons at the potential barrier in the tunneling dielectric 102 causes a lower probability of electron tunneling. Conversely the tunneling dielectric 102 presents a much lower resistance during the “on” state because the presence of more electrons as a result of the ion density in the solid electrolyte 90 increases the probability of electron tunneling.

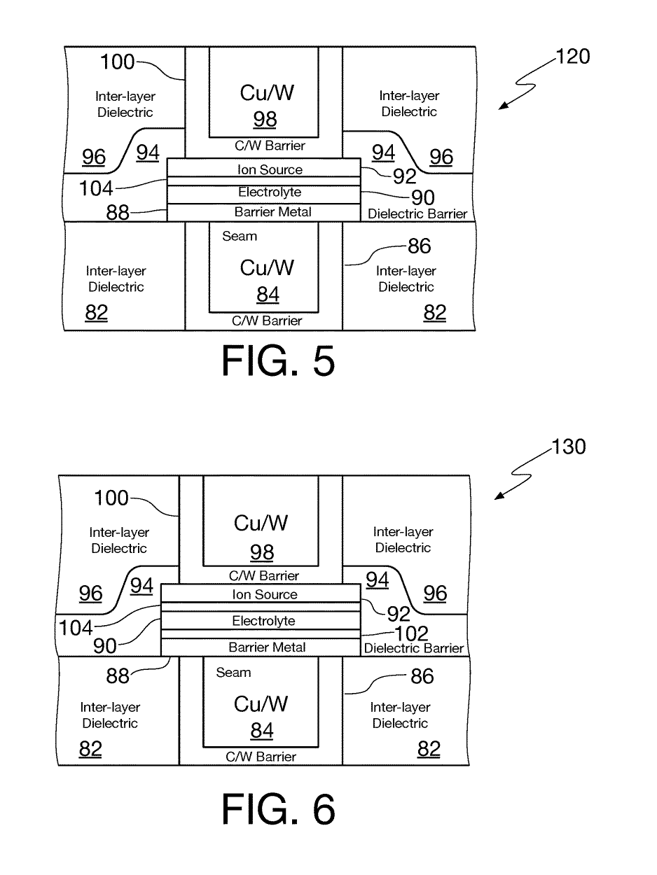

Referring now to FIG. 5, a diagram shows a cross-sectional view of an illustrative ReRAM device 120 in accordance with another aspect of the present invention. According to the aspect of the present invention illustrated in FIG. 5, ReRAM device 120 is in some respects similar to the embodiment depicted in FIG. 4. Thus ReRAM device 120 is formed over a damascene copper interconnect layer or a deposited tungsten via 84 in an interlayer dielectric layer 82 (or over any other metal interconnect structure) and includes a stacked structure including a barrier metal layer 88, a solid electrolyte layer 90, and an ion source layer 92.

A thin dielectric layer 104 formed from a material such as SiO₂ is placed between the top of the solid electrolyte layer 90 and the ion source layer 92. Other materials, such as SiN, doped SiO₂, SiOxyNitride, may be used. The thickness of the thin dielectric layer 104 may range from about 5 Å to about 100 Å, typical thicknesses being from about 20 Å to about 30 Å.

The use of the thin dielectric layer 104 will reduce leakage of ReRAM device 120 in the “off” state, since the area of the metal/electrolyte interconnect is reduced, as described below.

In the “off” state, some electrons do pass through the solid electrolyte layer 90 as leakage. The number of electrons that get through the solid electrolyte layer 90 is a function of the interface between the ion source layer 92 and the solid electrolyte layer 90. Given the present state of integrated circuit fabrication technology, a square area of interface between ion source layer 92 and the solid electrolyte layer 90 having an area of about 32 nm×32 nm is possible to achieve. By placing the thin dielectric layer 104 at this interface, a portion of the dielectric layer is punched through during the initial programming process. In particular, during initial programming some tunneling occurs, but some destructive punch through also occurs.

Because of the nature of the punch-through mechanism, the initial punch-through process occurs over only a portion of the thin dielectric layer 104, since the punch through follows the path of least resistance. This results in a reduced area of contact (much less than 32 nm×32 nm) between the solid electrolyte layer 90 and the ion source layer 92.

Referring now to FIG. 6, a diagram shows a cross-sectional view of an illustrative ReRAM device 130 in accordance with another aspect of the present invention.

ReRAM device 130 is a combination of the embodiments depicted in FIG. 4 and FIG. 5. ReRAM device 130 is formed over a metal layer 84 (shown for illustration as a damascene copper or tungsten plug structure) and includes a stacked structure including a barrier metal layer 88, an tunneling dielectric layer 102, a solid electrolyte layer 90, a thin dielectric layer 104, and an ion source layer 92.

ReRAM device 130 thus includes both the ultra-thin dielectric tunneling layer 102 of FIG. 5 and the thin dielectric layer 104 of FIG. 5.

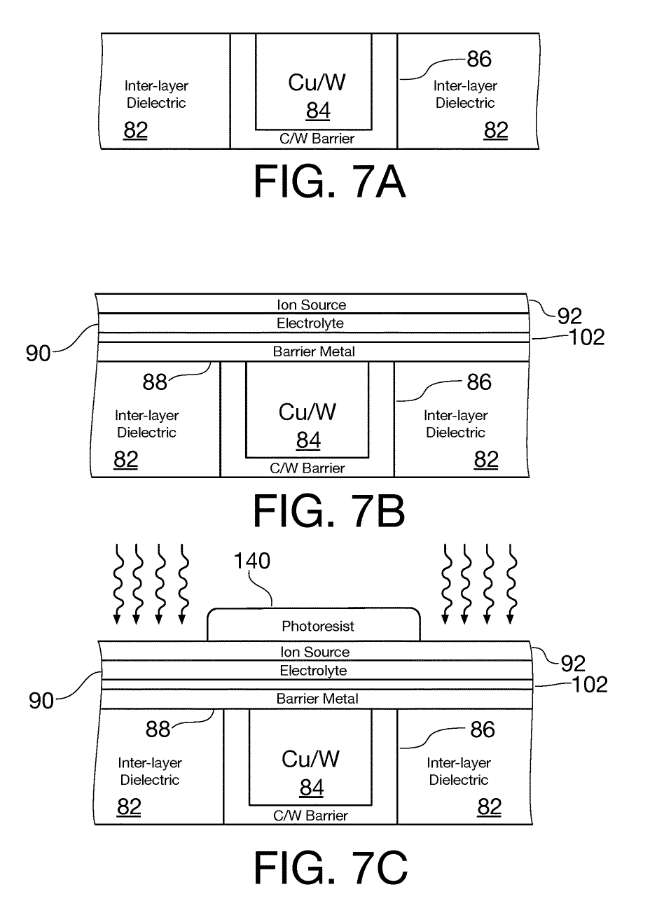

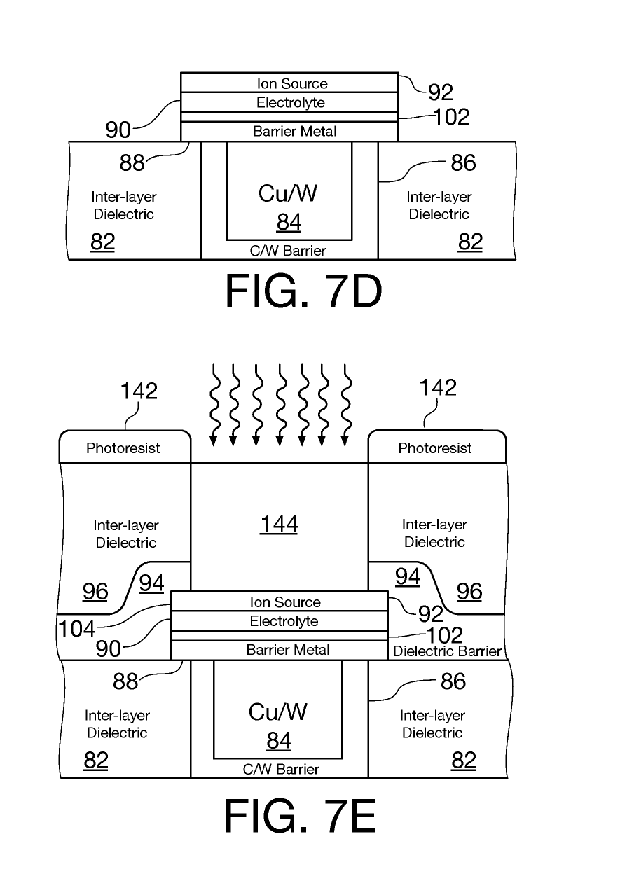

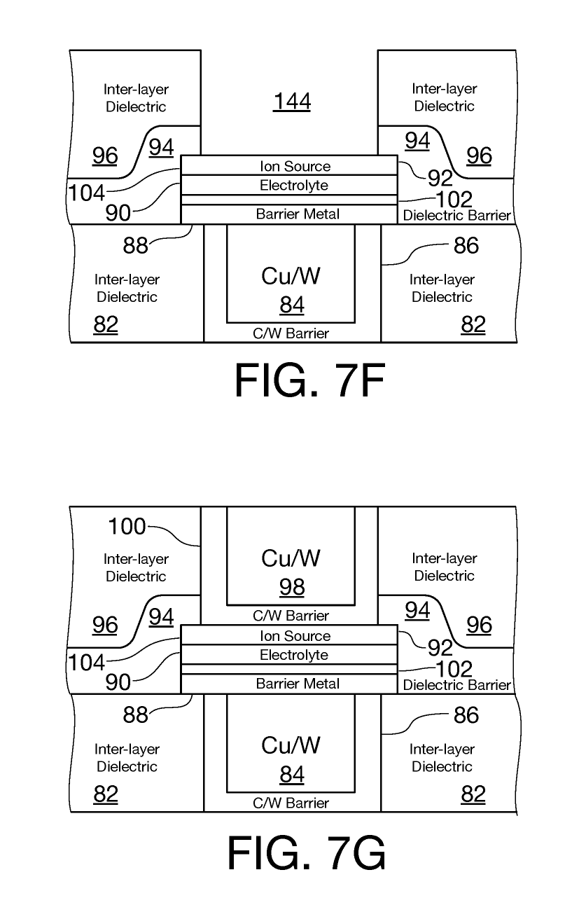

Referring now to FIGS. 7A through 7G, cross-sectional views of an illustrative ReRAM device depicting an illustrative process for fabricating the memory devices described above by showing the structure resulting after various steps in the semiconductor fabrication process have been performed.

The processes for fabricating the ReRAM devices shown in FIG. 4 through FIG. 6 include individual conventional deposition, etching, and other process steps performed in CMOS processes for fabricating integrated circuit devices.

FIG. 7A shows the structure resulting after prior steps have been performed to form a damascene copper metal line or tungsten plug 84 having a barrier metal lining 86 in an inter-layer dielectric layer 82 and to planarize the upper surface of the structure using known techniques such as CMP planarization.

Next, as shown in FIG. 7B, barrier metal layer 88, ultra-thin tunneling dielectric layer 102, solid electrolyte layer 90, and ion source layer 92 are blanket deposited over the planarized surface of inter-layer dielectric layer 82 and damascene copper metal line or tungsten plug 84. FIG. 7B shows the structure resulting after barrier metal layer 88, ultra-thin tunneling dielectric layer 102, solid electrolyte layer 90, and ion source layer 92 have been blanket deposited.

Next, as shown in FIG. 7C the surface is masked and an etching step is performed to etch the stack including barrier metal layer 88, tunneling dielectric layer 102, solid electrolyte layer 90, and ion source layer 92. FIG. 7C shows the etching step being performed through the photoresist layer 140.

Next, as shown in FIG. 7D, the photoresist layer 140 is removed and the resulting structure includes the stack of barrier metal layer 88, ultra-thin tunneling dielectric layer 102, solid electrolyte layer 90, and ion source layer 92.

Next, as shown in FIG. 7E, a dielectric barrier layer 94 is formed to seal and isolate the side edges of the stack including barrier metal layer 88, ultra-thin tunneling dielectric layer 102, solid electrolyte layer 90, and ion source layer 92. An interlayer dielectric layer 96 is deposited over dielectric barrier layer 94. A masking step is performed to form photoresist layer 142 to define an aperture in regions 144 for the upper metal layer. An etching step is performed to expose the top surface of ion source layer 92. FIG. 7E shows the etching step being performed through the photoresist layer 142.

Next, as shown in FIG. 7F, the photoresist layer 142 is removed and the top surface of ion source layer 92 is exposed at the bottom of aperture 144.

Next, as shown in FIG. 7G, aperture 144 is lined with a barrier metal layer 100 and a damascene copper layer or a tungsten plug 98 is formed in aperture 144. FIG. 7G shows the structure remaining after these process steps have been performed. Persons of ordinary skill in the art will appreciate that a conventional metal line, formed from a blanket deposited and etched layer of Al can be utilized instead of a damascene copper layer or a tungsten plug 98.

Persons of ordinary skill in the art will readily observe that FIGS. 7A through 7G illustrate an exemplary process for forming the ReRAM device structure of FIG. 4. Such ordinarily skilled persons will readily understand that the embodiments of the ReRAM device depicted in FIG. 5 and FIG. 6 can be fabricated using essentially the same process, the differences being that a deposition step for forming the thin dielectric layer 104 between the electrolyte layer 90 and the ion source layer 92 is performed either instead of or in addition to the deposition step for forming ultra-thin tunneling dielectric layer 102, depending on whether it is desired to fabricate the ReRAM device of FIG. 5 or the ReRAM device of FIG. 6.

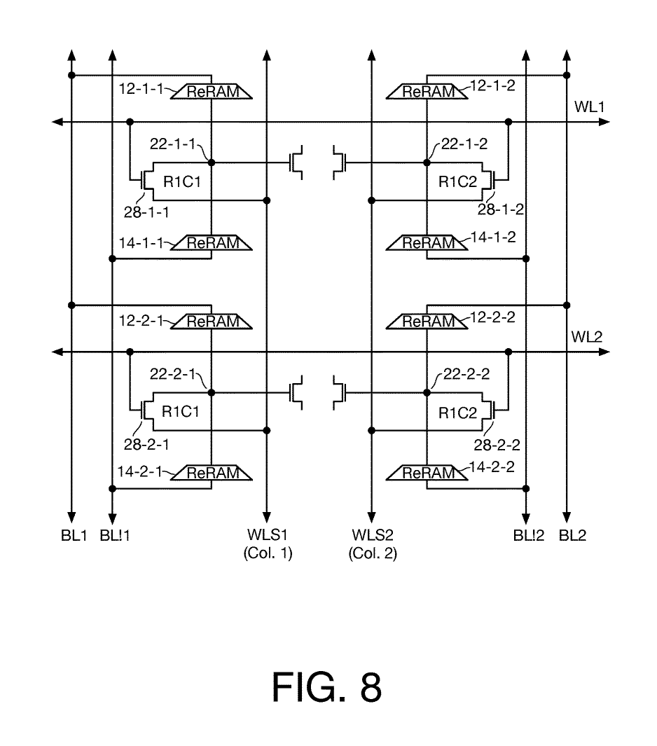

Referring now to FIG. 8, a schematic diagram depicts four illustrative ReRAM cells in an array to show a method for programming and erasing the ReRAM cells. The cells are identified by row and column location, R1C1 being the cell in the first row and first column, R1C2 being the cell in the first row second column, R2C1 being the cell in the second row and first column, and R2C2 being the cell in the second row second column.

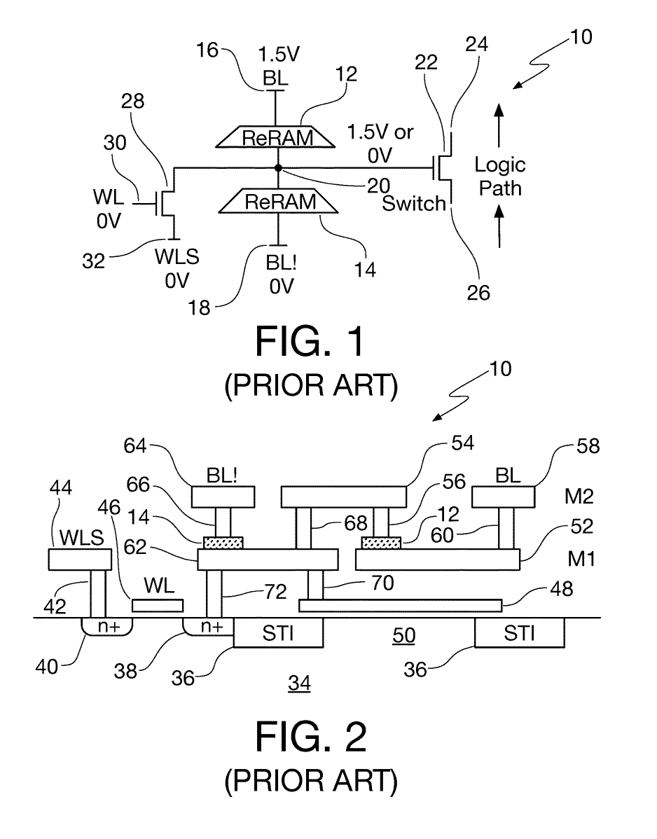

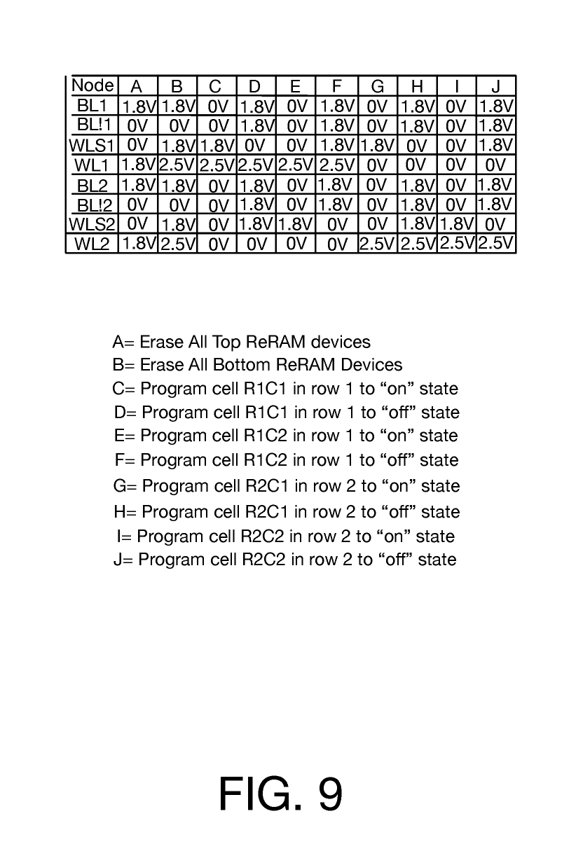

The table of FIG. 9 shows the voltages to apply to the column lines, bit lines and word lines to perform the operations associated with each column of the table. The reference numeral designations used for the elements in FIG. 8 are the reference numerals used for these elements in FIG. 1, followed by -x-y where x is the row of the array containing the element and y is the column of the array containing the element.

The voltages listed in FIG. 9 are nominal values and may vary in different designs as a function of the technology used. For example, 2.5V is applied to one of WL1 and WL2 for certain operations. The voltage actually necessary to perform these operations depends on the Vₜ of the programming transistors 28 (e.g., about 0.4V) and will therefore normally be less than 2.5V, but 2.5V is chosen because it is a voltage that usually present anyway in the integrated circuit and so is a convenient choice. The same is true for the 1.8V voltage values, which are normally present in integrated circuits, 1.8V being a typical voltage available to overdrive transistor gates to eliminate the Vₜ voltage drop across a turned on transistor.

Before programming any of the ReRAM cells, they are all erased by placing both of the ReRAM devices in the ReRAM cells to their “off” states.

Column A represents the voltages applied to erase (turn off) all upper ReRAM devices in the cells. When the voltages listed in column A of the table are applied to the array of FIG. 5,each of the programing transistors 28-1-1, 28-1-2, 28-2-1, and 28-2-2 in the four ReRAM memory cells R1C1, R1C2, R2C1, and R2C2 has 0V on its source and 1.8V on its gate and is turned on, placing each switch node 22-1-1, 22-1-2, 22-2-1, and 22-2-2 at 0V. The upper bitlines BL1 and BL2 each have 1.8V on them. Thus, the upper ReRAM devices 12-1-1, 12-1-2, 12-2-1, and 12-2-2 each have 1.8V across them, allowing current to flow through them to draw ions out of the electrolyte layer back to the ion source layer. The lower bitlines BL1! and BL2! each have 0V on them. Thus, the lower ReRAM devices 14-1-1, 14-1-2, 14-2-1, and 14-2-2 each have 0V across them, thus not allowing any current to flow through them.

Column B represents the voltages applied to erase all lower ReRAM devices in the cells. When the voltages listed in column B of the table are applied to the array of FIG. 5, each of the programing transistors 28-1-1, 28-1-2, 28-2-1, and 28-2-2 in the four ReRAM memory cells R1C1, R1C2, R2C1, and R2C2 has 1.8V on its source and 2.5V on its gate and is turned on, placing each switch node 22-1-1, 22-1-2, 22-2-1, and 22-2-2 at 1.8V. The lower bitlines BL1! and BL2! each have 0V on them. Thus, the lower ReRAM devices 14-1-1, 14-1-2, 14-2-1, and 14-2-2 each have 1.8V across them, allowing current to flow through them to draw ions out of the electrolyte layer back to the ion source layer. The upper bitlines BL1 and BL2 each have 1.8V on them. The upper ReRAM devices 12-1-1, 12-1-2, 12-2-1, and 12-2-2 thus each have 0V across them, not allowing any allowing current to flow through them.

Once all of the ReRAM cells have been erased, each ReRAM cell may be programmed to turn it “on” thereby turning on its associated switch transistor or to turn it “off” thereby turning off its associated switch transistor. As described below, the programming is accomplished responsive to the proper bias of the bitlines, word lines and respective programming transistor.

Column C represents the voltages applied to turn on the ReRAM cell at R1C1 by turning on the upper ReRAM device 12-1-1 in that cell to pull up the switch node to turn on the switch transistor. When the voltages listed in column C of the table are applied to the array of FIG. 5, programming transistor 28-1-1 has 1.8V on its source, 2.5V on its gate and will be turned on, driving the switch node 22-1-1 in ReRAM cell R1C1 to 1.8V. Bitline BL1 has 0V on it, and ReRAM device 12-1-1 will therefore have a voltage of 1.8V across it, the bottom end being more positive than the top end. This is the condition for programming ReRAM device 12-1-1. ReRAM device 14-1-1 will also have a voltage of 1.8V across it, but the bottom end is more negative than the top end and therefore ReRAM device 14-1-1 will not be programmed.

Programming transistor 28-1-2 has 0V on its source, 2.5V on its gate and will be turned on, driving the switch node 22-1-2 in ReRAM cell R1C2 to 0V. Because both BL2 and BL2! have 0V on them, both ReRAM devices 12-1-2 and 14-1-2 in ReRAM cell R1C2 will have 0V across them and will not be programmed.

Programming transistors 28-2-1 and 28-2-2 each has 0V on its gate and will be turned off. The switch nodes 22-2-1 and 22-2-2 in ReRAM cells R2C1 and R2C2 will be either floating or at the potential on both bitlines BL2 and BL2! if one of the ReRAM devices in those cells has been programmed. Since bitlines BL2 and BL2! are both at 0V, no ReRAM devices in cells R2C1 and R2C2 in the second row of the array will be programmed.

Column D represents the voltages applied to turn off the ReRAM cell at R1C1 by turning on the lower ReRAM device 14-1-1 in that cell to pull down the switch node 22-1-2 to turn off the associated switch transistor. When the voltages listed in column D of the table are applied to the array of FIG. 5, programming transistor 28-1-1 has 0V on its source, 2.5V on its gate and will be turned on, driving the switch node 22-1-1 in ReRAM cell R1C1 to 0V. Bitline BL1 has 1.8V on it, and ReRAM device 14-1-1 will have a voltage of 1.8V across it, the bottom end being more positive than the top end. This is the condition for programming ReRAM device 14-1-1. ReRAM device 12-1-1 will also have a voltage of 1.8V across it, but the bottom end is more negative than the top end and therefore ReRAM device 12-1-1 will not be programmed.

Programming transistor 28-1-2 has 1.8V on its source, 2.5V on its gate and will be turned on, driving the switch node 22-1-2 in ReRAM cell R1C2 to 1.8V. Because BL2 and BL2! both have 1.8V on them, both ReRAM devices 12-1-2 and 14-1-2 in ReRAM cell R1C2 will have 0V across them and will not be programmed.

Programming transistors 28-2-1 and 28-2-2 each has 0V on its gate and will be turned off. The switch nodes 22-2-1 and 22-2-2 in ReRAM cells R2C1 and R2C2 will be either floating or at the potential on both bitlines BL2 and BL2! if one of the ReRAM devices in those cells has been programmed. All bitlines are at 1.8V, but because the switch nodes 22-2-1 and 22-2-2 are either floating or at the potential of bitlines BL2 and BL!2, no ReRAM devices in cells R2C1 and R2C2 in the second row of the array will be programmed.

Column E represents the voltages applied to turn on the ReRAM cell at R1C2 by turning on the upper ReRAM device 12-1-2 in that cell to pull up the switch node 22-1-2 to turn on the associated switch transistor. The conditions are similar to those for column C, except that the source of programming transistor 28-1-2 is now at 1.8V and is turned on (and the source of transistor 28-1-1 is now at 0V) and ReRAM device 12-1-2 is programmed because it has 0V at its top end and 1.8V on its bottom end. ReRAM device 14-1-2 will also have a voltage of 1.8V across it, but its bottom end is more negative than its top end and therefore ReRAM device 14-1-2 will not be programmed. Persons of ordinary skill in the art will appreciate that the ReRAM cells in the second row of the array are not programmed for the reasons set forth in the explanation of the column C conditions.

Column F represents the voltages applied to turn off the ReRAM cell at R1C2 by turning on the lower ReRAM device 14-1-2 in that cell to pull down the switch node 22-1-2 to turn off the associated switch transistor. When the voltages listed in column F of the table are applied to the array of FIG. 9, programming transistor 28-1-2 has 0V on its source, 2.5V on its gate and will be turned on, driving the switch node 22-1-2 in ReRAM cell R1C2 to 0V. Bitline BL2 has 1.8V on it, and ReRAM device 14-1-2 will have a voltage of 1.8V across it, since bitline BL2 has 1.8V on it, the bottom end being more positive than the top end. This is the condition for programming ReRAM device 14-1-2. ReRAM device 12-1-2 will also have a voltage of 1.8V across it, but the bottom end is more negative than the top end and therefore ReRAM device 12-1-2 will not be programmed.

Programming transistor 28-1-1 has 1.8V on its source, 2.5V on its gate and will be turned on, driving the switch node 22-1-1 in ReRAM cell R1C1 to 1.8V. Because BL1 and BL1! both have 1.8V on them, both ReRAM devices 12-1-1 and 14-1-1 in ReRAM cell R1C1 will have 0V across them and will not be programmed.

Programming transistors 28-2-1 and 28-2-2 each has 0V on its gate and will be turned off. The switch nodes 22-2-1 and 22-2-2 in ReRAM cells R2C 1 and R2C2 will be either floating or at the potential on both bitlines BL1 and BL1! if one of the ReRAM devices in those cells has been programmed. All bitlines are at 1.8V, but because the switch nodes 22-2-1 and 22-2-2 are either floating or at the potential of bitlines BL1 and BL2!, no ReRAM devices in cells R2C1 and R2C2 in the second row of the array will be programmed.

Column G represents the voltages applied to turn on the ReRAM cell at R2C1 by turning on the upper ReRAM device 12-2-1 in that cell to pull up the switch node 22-2-1 to turn on the associated switch transistor. Column H represents the voltages applied to turn off the ReRAM cell at R2C1 by turning on the lower ReRAM device 14-2-1 in that cell to pull down the switch node 22-2-1 to turn off the associated switch transistor. Column I represents the voltages applied to turn on the ReRAM cell at R2C2 by turning on the upper ReRAM device 12-2-2 in that cell to pull up the switch node 22-2-2 to turn on the associated switch transistor. Column J represents the voltages applied to turn off the ReRAM cell at R2C1 by turning on the lower ReRAM device 14-2-2 in that cell to pull down the switch node 22-2-1 to turn off the associated switch transistor. From the conditions described with reference to columns C through F for programming the ReRAM cells in the first row of the array to either their “on” or “off” states, persons of ordinary skill in the art will readily appreciate from FIG. 8 and FIG. 9 how the programming of ReRAM cells R2C1 and R2C2 in the second row of the array is accomplished.

While embodiments and applications of this invention have been shown and described, it would be apparent to those skilled in the art that many more modifications than mentioned above are possible without departing from the inventive concepts herein. The invention, therefore, is not to be restricted except in the spirit of the appended claims.

What is claimed is:

1. A resistive random access memory device formed in an integrated circuit between a first metal layer and a second metal layer and comprising:
a first barrier layer disposed over the first metal layer;
a tunneling dielectric layer disposed over the first barrier layer;
a solid electrolyte layer disposed over the tunneling dielectric layer;
an ion source layer disposed over the solid electrolyte layer; and
a second barrier layer disposed over the ion source layer.

2. A resistive random access memory device formed in an integrated circuit and comprising:
a first metal layer;
a first barrier layer disposed over the first metal layer;
a tunneling dielectric layer disposed over the first barrier layer;
a solid electrolyte layer disposed over the tunneling dielectric layer;
an ion source layer disposed over the solid electrolyte layer;
a second barrier layer disposed over the ion source layer; and
a second metal layer disposed over the second barrier layer.

3. A resistive random access memory device formed in an integrated circuit between a first metal layer and a second metal layer and comprising:
a first barrier layer disposed over the first metal layer;
a solid electrolyte layer disposed over the first barrier layer;
a dielectric layer disposed over the solid electrolyte layer;
an ion source layer disposed over the dielectric layer; and
a second barrier layer disposed over the ion source layer and beneath the second metal layer.

4. A resistive random access memory device formed in an integrated circuit between a first metal layer and a second metal layer and comprising:
a first barrier layer disposed over the first metal layer;
a tunneling dielectric layer disposed over the first barrier layer;
a solid electrolyte layer disposed over the tunneling dielectric layer;
a dielectric layer disposed over the solid electrolyte layer;
an ion source layer disposed over the dielectric layer; and
a second barrier layer disposed over the ion source layer and beneath the second metal layer.

5. A method for forming a resistive random access memory device in an integrated circuit between a first metal layer and a second metal layer comprising:
forming a first barrier layer disposed over the first metal layer;
forming a tunneling dielectric layer disposed over the first barrier layer;
forming a solid electrolyte layer disposed over the tunneling dielectric layer;
forming an ion source layer disposed over the solid electrolyte layer; and
forming a second barrier layer disposed over the ion source layer.

6. The method of claim 5, further including:
forming a dielectric layer over the solid electrolyte layer before forming the ion source layer.

7. A method for forming a resistive random access memory device in an integrated circuit between a first metal layer and a second metal layer comprising:
forming a first barrier layer disposed over the first metal layer;
forming a tunneling dielectric layer disposed over the first barrier layer;
forming a solid electrolyte layer disposed over the tunneling dielectric layer;
forming an ion source layer disposed over the solid electrolyte layer;
forming a second barrier layer disposed over the ion source layer; and
forming a second metal layer disposed over the second barrier layer.

8. A method for forming a resistive random access memory device in an integrated circuit between a first metal layer and a second metal layer comprising:
forming a first barrier layer disposed over the first metal layer;
forming a solid electrolyte layer disposed over the first barrier layer;
forming a dielectric layer disposed over the solid electrolyte layer;
forming an ion source layer disposed over the dielectric layer; and
forming a second barrier layer disposed over the ion source layer and beneath the second metal layer.
